(19) United States
(12) Patent Application Publication
(10) Pub. No.: US 2025/0386746 A1
(43) Pub. Date: Dec. 18, 2025

(54) VARIABLE RESISTANCE MEMORY DEVICE

(71) Applicant: SAMSUNG ELECTRONICS CO., LTD., SUWON-SI (KR)

(72) Inventors: Hyun Seok LEE, Cheongju-si (KR); Min CHOI, Cheongju-si (KR)

(73) Assignee: Chungbuk National University Industry-Academic Cooperation Foundation, Cheongju (KR)

(21) Appl. No.: 18/984,064

(22) Filed: Dec. 17, 2024

(30) Foreign Application Priority Data
Jun. 12, 2024 (KR) 10-2024-0076611

(51) Int. Cl. H10N 70/00; H10B 63/00

(52) U.S. Cl. CPC H10N 70/8418; H10B 63/80; H10N 70/8822; H10N 70/8825; H10N 70/883

(57) ABSTRACT

A variable resistance memory device including: a first electrode; a second electrode facing the first electrode; and a resistance variable portion between the first electrode and the second electrode, wherein the resistance variable portion generates or interrupts a current flow to change a resistance in response to a change in voltage applied between the first electrode and the second electrode, and the current flow is generated or interrupted at a location between the first electrode and the second electrode.

### CROSS-REFERENCE TO RELATED APPLICATION

This application claims priority under 35 U.S.C. § 119 to Korean Patent Application No. 10-2024-0076611, filed on Jun. 12, 2024, in the Korean Intellectual Property Office, the disclosure of which is incorporated by reference herein in its entirety.

### TECHNICAL FIELD

The inventive concept relates to a variable resistance memory device, and more particularly, to a variable resistance memory device having an improved lifespan and performance characteristics.

### DISCUSSION OF RELATED ART

Semiconductor memory devices require higher operating speeds and greater integration levels. To meet these demands, variable resistance memory devices have been developed, utilizing the current transfer properties of a variable resistance layer influenced by an applied voltage.

In recent years, variable resistance memory devices have gained attention as promising candidates for memory technology due to their simple structure, long data retention, high operating speed, ultra-low power consumption, and suitability for three-dimensional architectures.

### SUMMARY

The inventive concept provides a variable resistance memory device having an improved lifespan and performance characteristics.

According to an embodiment of the inventive concept, there is provided a variable resistance memory device including: a first electrode; a second electrode facing the first electrode; and a resistance variable portion between the first electrode and the second electrode, wherein the resistance variable portion generates or interrupts a current flow to change a resistance in response to a change in voltage applied between the first electrode and the second electrode, and the current flow is generated or interrupted at a location between the first electrode and the second electrode.

According to an embodiment of the inventive concept, there is provided a variable resistance memory device including: a first electrode and a second electrode spaced apart from each other; a plurality of vertical alignment layers extending from the first electrode toward the second electrode and spaced apart from each other; and a current transfer path in a separation space between the vertical alignment layers, wherein at least one of the vertical alignment layers includes an insulating material.

According to an embodiment of the inventive concept, there is provided a variable resistance memory device including: a substrate; a first electrode on the substrate; a second electrode arranged on the first electrode and spaced apart from the first electrode; a plurality of vertical alignment layers extending from the first electrode toward the second electrode, spaced apart from each other, and having insulating characteristics; a current transfer path located in a separation space between the vertical alignment layers; and a conductive filament that is generated or extinguished in the current transfer path, wherein the conductive filament is generated or extinguished according to a change in a voltage applied between the first electrode and the second electrode, and at least one of the vertical alignment layers is vertically aligned toward the second electrode on the first electrode.

### BRIEF DESCRIPTION OF THE DRAWINGS

Embodiments of the inventive concept will be more clearly understood from the following detailed description taken in conjunction with the accompanying drawings in which:

FIG. 1 is a schematic perspective view illustrating a variable resistance memory device according to an embodiment;

FIG. 2A is a schematic configuration diagram showing a variable resistance memory device in which a conductive filament is generated;

FIG. 2B is a schematic configuration diagram showing a variable resistance memory device in which a portion of a conductive filament is extinguished;

FIG. 3 is a graph showing the current-voltage characteristics of a variable resistance memory device according to the related art;

FIG. 4 is a graph showing the current-voltage characteristics of a variable resistance memory device according to an embodiment;

FIGS. 5A, 5B and 5C are schematic cross-sectional views showing processes of a method of manufacturing a variable resistance memory device according to an embodiment;

FIG. 6 is a schematic block diagram illustrating an electronic apparatus including a variable resistance memory device according to an embodiment;

FIG. 7 is a schematic block diagram illustrating a memory system including a variable resistance memory device according to an embodiment; and

FIG. 8 is a schematic diagram illustrating a neuromorphic apparatus including a variable resistance memory device according to an embodiment.

### DETAILED DESCRIPTION OF THE EMBODIMENTS

Hereinafter, embodiments of the inventive concept are described in detail with reference to the attached drawings. However, the inventive concept is not limited to the embodiments described below and may be embodied in various other forms.

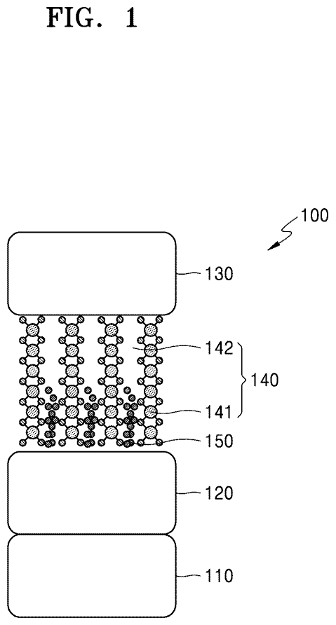

FIG. 1 is a schematic perspective view illustrating a variable resistance memory device according to an embodiment.

Referring to FIG. 1, a variable resistance memory device 100 according to an embodiment may include a substrate 110, a first electrode 120, a second electrode 130, a resistance variable portion 140, and a conductive filament 150.

The substrate 110 may include various substrates. The substrate 110 may include, for example, a silicon layer and a silicon oxide layer located on the silicon layer. The substrate 110 may include, for example, a glass layer. However, this is an example and the inventive concept is not limited thereto.

The first electrode 120 may be located on the substrate 110. For example, the first electrode 120 may be in direct contact with the substrate 110. The first electrode 120 may include a conductive material, for example, at least one of platinum, aluminum, copper, gold, silver, iron, palladium, titanium, zinc, molybdenum, tungsten, nickel, niobium, rubidium, iridium, tantalum, chromium, n-type silicon, p-type silicon, indium-tin oxide, and an alloy thereof.

The second electrode 130 may face the first electrode 120 and may be spaced apart from the first electrode 120. The second electrode 130 may include a conductive material, for example, at least one of platinum, aluminum, copper, gold, silver, iron, palladium, titanium, zinc, molybdenum, tungsten, nickel, niobium, rubidium, iridium, tantalum, chromium, n-type silicon, p-type silicon, indium-tin oxide, and an alloy thereof. The first electrode 120 and the second electrode 130 may contain the same material as each other. In the alternative, the first electrode 120 and the second electrode 130 may be composed of different materials.

The resistance variable portion 140 may be located between the first electrode 120 and the second electrode 130. The resistance variable portion 140 may generate or extinguish at least one current flow depending on a change in voltage applied between the first electrode 120 and the second electrode 130. In other words, the resistance variable portion 140 may generate or interrupt one or more current flows depending on changes in the voltage applied between the first electrode 120 and the second electrode 130. Current flow is a state in which oxygen vacancies or metal ions are freely mobile. In other words, current flow occurs when oxygen vacancies or metal ions are freely mobile.

When current flows between the first electrode 120 and the second electrode 130, the resistance variable portion 140 may enter a low resistance state LRS. Conversely, when current flow is partially or completely eliminated, the resistance variable portion 140 may enter a high resistance state HRS.

Current flow may result from a conductive filament. The conductive filament may be formed by the movement of metal ions or oxygen vacancies within the resistance variable portion 140. When a voltage is applied between the first electrode 120 and the second electrode 130, metal ions or oxygen vacancies may migrate from the first electrode 120 to the second electrode 130 or from the second electrode 130 to the first electrode 120, establishing current flow. This current flow corresponds to the formation of the conductive filament.

The resistance variable portion 140 may include, for example, a vertical alignment layer 141 and a current transfer path 142.

A plurality of vertical alignment layers 141 may be arranged in a stack structure, with each layer having a two-dimensional plate-like configuration. These layer are aligned in a direction from the surface of the first electrode 120 toward the surface of the second electrode 130, facing the surface of the first electrode 120.

Each of the plurality of vertical alignment layers 141 may be spaced apart from each other in a direction that intersects the path from the first electrode 120 to the second electrode 130. The space between the plurality of vertical alignment layers 141 forms the current transfer path 142, where the current flow generated or extinguished.

According to an embodiment, the plurality of vertical alignment layers 141 may interact with each other through van der Waals forces. In detail, the bonding between the plurality of vertical alignment layers 141 is established by van der Waals interactions, with a bonding strength lower than that within each individual layer of the plurality of vertical alignment layers 141. Due to this relatively low bonding strength, a van der Waals gap may be formed between the plurality of vertical alignment layers 141, which serves as the current transfer path 142.

The variable resistance memory device 100 according to an embodiment may ensure device reliability by directing current flow through the current transfer path 142. Unlike conventional devices, where conductive filaments form randomly within an insulating layer between electrodes (compromising uniformity and reliability), the variable resistance memory device 100 ensures that conductive filaments are generated or extinguished solely within the pre-formed current transfer path 142 in the resistance variable portion 140. This design improves an input/output current ratio (on/off ratio) and cycle count, and enables precise control of a switching mechanism.

Each of the plurality of vertical alignment layers 141 may have a two-dimensional layer structure and may include an insulating material. For example, the plurality of vertical alignment layers 141 may include a transition metal oxide. The transition metal oxide may include molybdenum oxide (MoOx) or tungsten oxide (WOx).

The transition metal oxide of the plurality of vertical alignment layers 141 may be formed by oxidizing transition metal dichalcogenide. This is described below.

As described above, the current transfer path 142 may be defined by a separation space between the vertical alignment layers 141. The current transfer path 142 may be formed by spacing the vertical alignment layers 141 apart from each other through van der Waals interactions between adjacent vertical alignment layers 141.

The current flow may be generated or extinguished in the current transfer path 142. The current flow may be obtained by forming conductive filaments within the current transfer path 142.

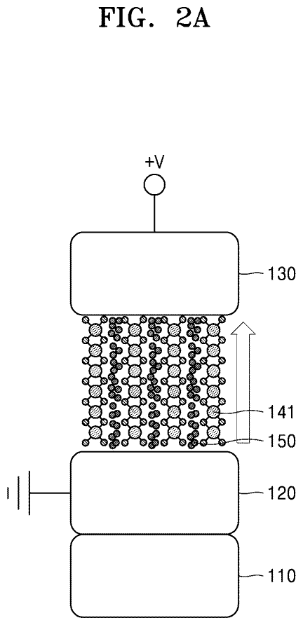

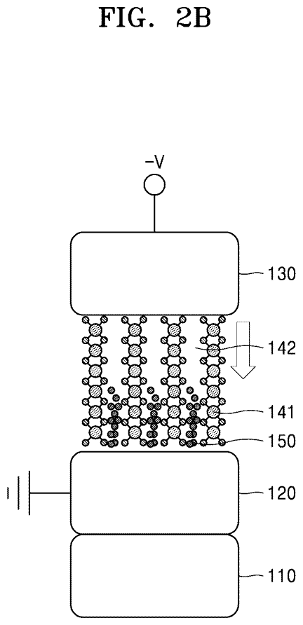

FIG. 2A is a schematic configuration diagram showing a variable resistance memory device in which the conductive filament 150 is generated. FIG. 2B is a schematic configuration diagram showing a variable resistance memory device in which a portion of the conductive filament 150 is extinguished.

Referring to FIG. 2A, the variable resistance memory device 100 may have the resistance variable portion 140 in a low resistance state when the first electrode 120 is grounded and a predetermined positive voltage (+V) is applied to the second electrode 130. In other words, metal from the first electrode 120 may migrate into the current transfer path 142 to form the conductive filament 150. This is indicated by the arrow in FIG. 2A. During this migration, the metal can exist in an atomic state or in a cationic state. Accordingly, the conductive filament 150 may electrically connect the first electrode 120 to the second electrode 130. In detail, the first electrode 120, the conductive filament 150, and the second electrode 130 may be physically connected to each other to form an electrical path.

Referring to FIG. 2B, when a predetermined negative voltage (−V) is applied to the second electrode 130 (as indicated by the arrow), the conductive filament 150 may be extinguished. Accordingly, the metal discharged from the first electrode 120 may not electrically connect the first electrode 120 to the second electrode 130. In other words, the metal released from the first electrode 120 will no longer form an electrical connection between the first electrode 120 and the second electrode 130. Here, the resistance variable portion 140 may be in a high resistance state. In detail, the first electrode 120, the conductive filament 150, and the second electrode 130 may not be physically connected to each other and thus may not form an electrical path.

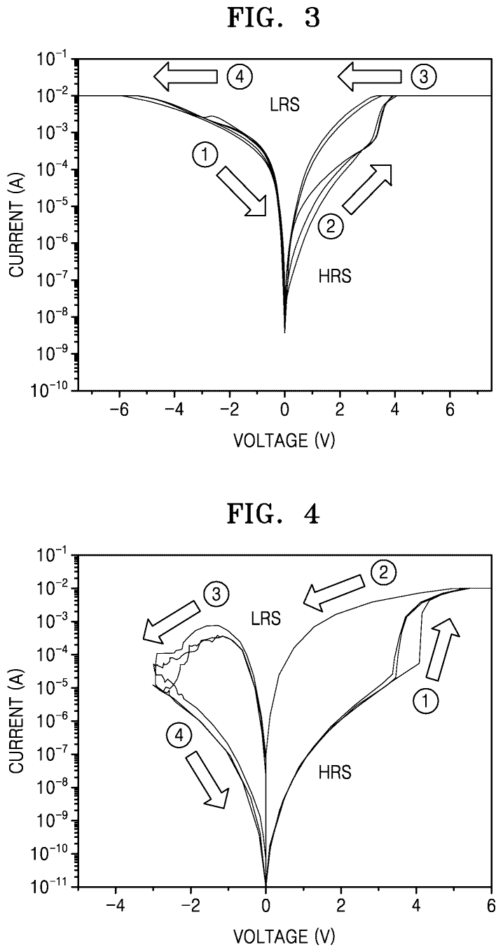

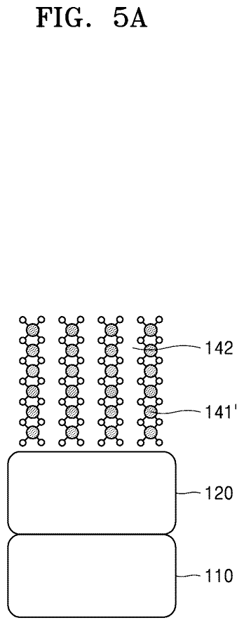

FIG. 3 is a graph showing a current depending on a voltage applied to a variable resistance memory device according to the related art. FIG. 4 is a graph showing a current depending on a voltage applied to a variable resistance memory device according to an embodiment.

The variable resistance memory device according to the related art of FIG. 3 may include a resistance variable portion formed by directly depositing MoO₃ on a first electrode, and the variable resistance memory device according to an embodiment of FIG. 4 may include a resistance variable portion formed by forming MoS₂ on a first electrode and then oxidizing MoS₂ to form MoO₃.

Referring to FIGS. 3 and 4, during electrical measurements, an electrical bias is applied to the second electrode (e.g., upper electrode) and the first electrode (e.g., lower electrode) is grounded. To protect the resistance switching memory device, a compliance current (Icc) of 10⁻² A is applied thereto. The voltage is swept from 0 V to 6 V, then from 6 V to 0 V, followed by 0 V to −8 V, and −6 V to 0 V.

When the voltage is swept from 0 V to 6 V, the resistance switching memory device may transition from a high resistance state HRS to a low resistance state LRS, and when the voltage is swept back from 6 V to 0 V, the low resistance state LRS may be maintained.

When the voltage is swept from 0 V to 6 V, the current increases rapidly at 4 V, and the resistance switching memory device may transition from the high resistance state HRS to the low resistance state LRS. Then, when the voltage is swept back from 6 V to 0 V, the low resistance state LRS may be maintained. However, when the voltage is swept from 0 V to −6 V, the conventional variable resistance memory device does not clearly distinguish between the low resistance state LRS and the high resistance state HRS.

In contrast, the variable resistance memory device according to an embodiment exhibits a sharp decrease in current at −0.3 V, and transitions from the low resistance state LRS to the high resistance state HRS. The variable resistance memory device according to an embodiment maintains the high resistance state HRS as the voltage is swept from −3 V back to 0 V.

The hysteresis characteristics of the variable resistance memory device according to an embodiment are significantly improved compared to conventional devices, particularly in the range from 0 V to −6 V and 0 V to 6 V.

The on/off current ratio of the conventional variable resistance memory device is 10⁻⁹ A at 0 V, whereas the variable resistance memory device according to an embodiment achieves 10⁻¹¹ A at O V, representing an improvement of approximately 100 times or more.

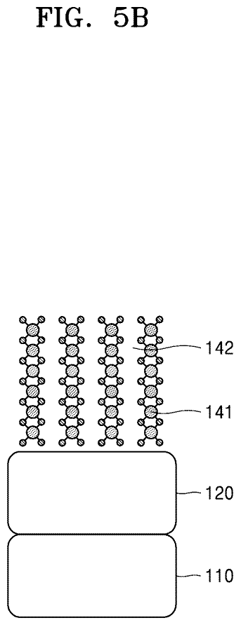

FIGS. 5A to 5C are schematic cross-sectional views showing processes of a method of manufacturing a variable resistance memory device according to an embodiment.

Referring to FIG. 5A, the first electrode 120 may be formed on the substrate 110, and a vertical layer 141′ may be formed on the first electrode 120.

The first electrode 120 may be formed on the substrate 110 through a deposition process. The first electrode 120 may include a conductive material, and may include, for example, at least one of platinum (Pt), aluminum (Al), copper (Cu), gold (Au), silver (Ag), iron (Fe), palladium (Pd), titanium (Ti), zinc (Zn), molybdenum (Mo), tungsten (W), nickel (Ni), niobium (Nb), rubidium (Rb), iridium (Ri), tantalum (Ta), chromium (Cr), n-type silicon (Si), p-type silicon, indium-tin oxide (ITO), and an alloy thereof.

The vertical layer 141′ may be formed on the first electrode 120. The vertical layer 141′ may be formed by vertically-aligning and directly growing the transition metal dichalcogenide on the first electrode 120. In detail, a plurality of vertical layers 141′ in the form of a two-dimensional flat plates perpendicular to the upper surface of the first electrode 120 may be grown on the first electrode 120 through a deposition process. The plurality of vertical layers 141′ may self-align with a preset spacing, creating spaces between the grown plurality of vertical layers 141′ that define the current transfer path 142. As such, the plurality of vertical layers 141′ may be formed directly on the first electrode 120 through a deposition process, enabling large-area mass production and easy adjustment of the thickness of the current transfer path 142.

According to an embodiment, the plurality of vertical layers 141′ may be formed through a deposition process such as, but not limited to, physical vapor deposition (PVD), chemical vapor deposition (CVD), sputtering, pulsed laser deposition (PLD), thermal evaporation, electron beam evaporation, atomic layer deposition (ALD), and molecular beam epitaxy (MBE).

The transition metal dichalcogenide may include at least one of MoS₂, MoSe₂, WS₂, or WSe₂.

Referring to FIG. 5B, the vertical alignment layer 141 may be formed by oxidizing the vertical layer 141′. In detail, the transition metal dichalcogenide of the vertical layer 141′ can undergo a phase transition to become a transition metal oxide in an oxygen atmosphere through a thermal or plasma oxidation process. The transition metal oxides may form the vertical alignment layer 141.

Even when the transition metal dichalcogenide is phase-transitioned into the transition metal oxide by a thermal or plasma oxidation process, a spacing between the vertical layers 141′ may be maintained, and a space between the vertical alignment layers 141 may be used as the current transfer path 142.

Referring to FIG. 5C, the second electrode 130 may be formed on the vertical alignment layer 141. The second electrode 130 may include a conductive material, for example, at least one of platinum, aluminum, copper, gold, silver, iron, palladium, titanium, zinc, molybdenum, tungsten, nickel, niobium, rubidium, iridium, tantalum, chromium, n-type silicon, p-type silicon, indium-tin oxide, and an alloy thereof.

The first electrode 120 and the second electrode 130 may include the same material or different materials.

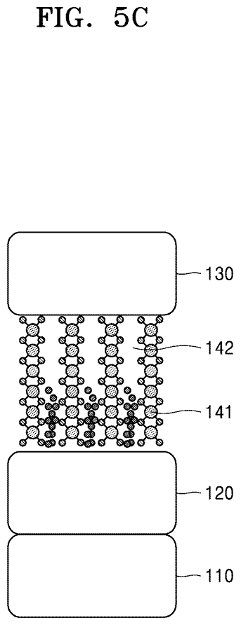

FIG. 6 is a schematic block diagram illustrating an electronic apparatus including a variable resistance memory device according to an embodiment.

Referring to FIG. 6, an electronic apparatus 200 according to an embodiment may be a personal digital assistant (PDA), a laptop computer, a portable computer, a web tablet, a cordless telephone, a mobile phone, a digital music player, a wired or wireless electronic apparatus, or at least two of these. The electronic apparatus 200 may include a controller 220, an input/output device 230 such as a keypad, a keyboard, or a display, a memory 240, and a wireless interface 250, which are coupled to each other via a bus 210.

The controller 220 may include, for example, one or more microprocessors, digital signal processors, microcontrollers, or the like. The memory 240 may be used, for example, to store instructions executed by the controller 220.

The memory 240 may be used to store user data. The memory 240 may include at least one of the variable resistance memory devices according to an embodiment.

The electronic apparatus 200 may use the wireless interface 250 to transmit data to or receive data from a wireless communications network that performs communication via radio frequency (RF) signals. For example, the wireless interface 250 may include an antenna and a wireless transceiver. The electronic apparatus 200 may be used in a communication interface protocol such as a 3rd generation communication system including code division multiple access (CDMA), Global System for Mobile Communications (GSM), Extended Time Division Multiple Access (E-TDMA), wideband code division multiple access (WCDAM), and code division multiple access 2000 (CDMA2000).

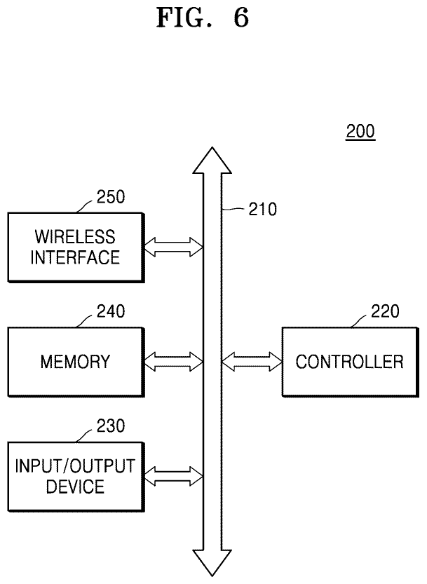

FIG. 7 is a schematic block diagram illustrating a memory system 300 including a variable resistance memory device according to an embodiment.

Referring to FIG. 7, variable resistance memory devices according to an embodiment may be used to implement a memory system. The memory system 300 may include a memory 310 and a memory controller 320 to store a large amount of data. The memory controller 320 controls the memory 310 to read or write data stored in the memory 310 in response to a read/write request from a host 330. The memory controller 320 may configure an address mapping table for mapping an address provided from the host 330, such as a mobile device or a computer system, to a physical address of the memory 310. The memory 310 may include at least one of the variable resistance memory devices according to an embodiment.

The variable resistance memory device according to the embodiments described thus far may be implemented in a chip form and used as a neuromorphic computing platform.

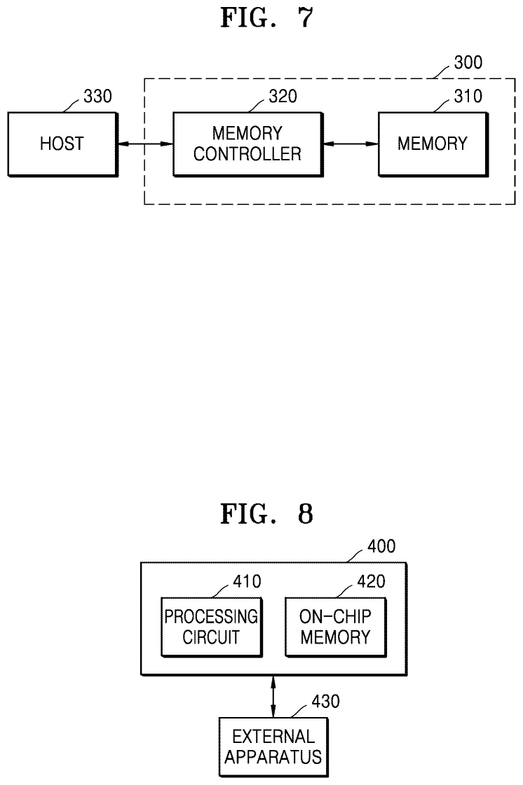

FIG. 8 is a schematic diagram illustrating a neuromorphic apparatus including a variable resistance memory device according to an embodiment.

Referring to FIG. 8, a neuromorphic apparatus 400 may include a processing circuit 410 and/or an on-chip memory 420. The on-chip memory 420 of the neuromorphic apparatus 400 may include a memory system according to an embodiment.

The processing circuit 410 may be configured to control functions for driving the neuromorphic apparatus 400. For example, the processing circuit 410 may control the neuromorphic apparatus 400 by executing a program stored in an on-chip memory 420 of the neuromorphic apparatus 400.

The processing circuit 410 may include hardware such as logic circuits, a combination of software and hardware such as a processor executing software, or a combination thereof. For example, the processor may include a central processing unit (CPU), a graphics processing unit (GPU), an application processor (AP), an arithmetic logic unit (ALU), a digital processor, a microcomputer, a field programmable gate array (FPGA), a system-on-chip (SoC), a programmable logic unit, a microprocessor, and an application-specific integrated circuit (ASIC).

The processing circuit 410 may read and write various data from an external apparatus 430 and operate the neuromorphic apparatus 400 by using the data. The external apparatus 430 may include a sensor array having an external memory and/or an image sensor (e.g., complementary metal-oxide semiconductor (CMOS) image sensor circuit).

The neuromorphic apparatus 400 shown in FIG. 8 may be applied to a machine learning system. The machine learning system may utilize various artificial neural network organizations and processing models, including, for example, a convolutional neural network (CNN), a deconvolutional neural network, a recurrent neural network (RNN), optionally including a long short-term memory (LSTM), and/or a gated recurrent unit (GRU), a stacked neural network (SNN), a state-space dynamic neural network (SSDNN), a deep belief network (DBN), a generative adversarial network (GAN), and/or a restricted Boltzmann machine (RBM).

The machine learning system may include combinations, including, for example, dimensionality reduction such as linear regression and/or logistic regression, statistical clustering, Bayesian classification, decision trees, and principal component analysis, and other types of machine learning models such as an expert system, and/or an ensemble scheme such as random forest. This machine learning model may be used to provide various services, such as an image classification service, a user authentication service based on biometric information or biometric data, an advanced driver assistance system (ADAS), a voice assistant service, and an automatic speech recognition (ASR) service and may be installed and executed in other electronic apparatuses.

As described above, embodiments are disclosed in the drawings and specification. Although certain terms are used in this specification, they are intended solely to explain the inventive concept's technical ideas and are not meant to limit the scope of the inventive concept set forth in the claims. Therefore, those of ordinary skill in the art will understand that various modifications and equivalent embodiments may arise from these disclosures.

While the inventive concept has been particularly shown and described with reference to embodiments thereof, it will be understood that various changes in form and details may be made thereto without departing from the spirit and scope of the inventive concept as set forth in the following claims.

What is claimed is:

1. A variable resistance memory device comprising:
a first electrode;
a second electrode facing the first electrode; and
a resistance variable portion between the first electrode and the second electrode,
wherein the resistance variable portion generates or interrupts a current flow to change a resistance in response to a change in voltage applied between the first electrode and the second electrode, and
the current flow is generated or interrupted at a location between the first electrode and the second electrode.

2. The variable resistance memory device of claim 1,
wherein the resistance variable portion includes:
a plurality of vertical alignment layers extending from the first electrode toward the second electrode and spaced apart from each other; and
a current transfer path in a separation space between the vertical alignment layers, and
the current flow is generated or interrupted in the current transfer path.

3. The variable resistance memory device of claim 2,
wherein the current transfer path is formed by spacing the vertical alignment layers apart from each other through van der Waals interactions between adjacent vertical alignment layers.

4. The variable resistance memory device of claim 2,
wherein the current flow is generated by a conductive filament formed within the current transfer path.

5. The variable resistance memory device of claim 2, wherein the vertical alignment layer includes a transition metal oxide.

6. The variable resistance memory device of claim 5, wherein the vertical alignment layer includes MoOx or WOx.

7. The variable resistance memory device of claim 2,
wherein the vertical alignment layer includes a transition metal oxide.

8. The variable resistance memory device of claim 7,
wherein the transition metal dichalcogenide includes at least one of MoS₂, MoSe₂, WS₂, or WSe₂.

9. The variable resistance memory device of claim 7,
wherein the transition metal dichalcogenide is vertically aligned toward the second electrode on the first electrode.

10. A variable resistance memory device comprising:
a first electrode and a second electrode spaced apart from each other;
a plurality of vertical alignment layers extending from the first electrode toward the second electrode and spaced apart from each other; and
a current transfer path in a separation space between the vertical alignment layers,
wherein at least one of the vertical alignment layers includes an insulating material.

11. The variable resistance memory device of claim 10, wherein a current flow is generated or stopped in the current transfer path.

12. The variable resistance memory device of claim 11,
wherein the current flow is generated by a conductive filament formed within the current transfer path.

13. The variable resistance memory device of claim 10, wherein the vertical alignment layer includes a transition metal oxide.

14. The variable resistance memory device of claim 13, wherein the vertical alignment layer includes MoOx or WOx.

15. The variable resistance memory device of claim 13,
wherein the transition metal oxide is based on an oxidized transition metal dichalcogenide.

16. The variable resistance memory device of claim 15,
wherein the transition metal dichalcogenide includes at least one of MoS₂, MoSe₂, WS₂, or WSe₂.

17. The variable resistance memory device of claim 15,
wherein the transition metal dichalcogenide is vertically aligned toward the second electrode on the first electrode.

18. A variable resistance memory device comprising:
a substrate;
a first electrode on the substrate;
a second electrode arranged on the first electrode and spaced apart from the first electrode;
a plurality of vertical alignment layers extending from the first electrode toward the second electrode, spaced apart from each other, and having insulating characteristics;
a current transfer path located in a separation space between the vertical alignment layers; and
a conductive filament that is generated or extinguished in the current transfer path,
wherein the conductive filament is generated or extinguished according to a change in a voltage applied between the first electrode and the second electrode, and
at least one of the vertical alignment layers is vertically aligned toward the second electrode on the first electrode.

19. The variable resistance memory device of claim 18,
wherein the vertical alignment layer includes a transition metal oxide.

20. The variable resistance memory device of claim 18, wherein the vertical alignment layer includes MoOx or WOx.
